(19) United States
(12) Patent Application Publication
(10) Pub. No.: US 2012/0241648 A1
(43) Pub. Date: Sep. 27, 2012

(54) HEAT LIP SEAL FOR CRYOGENIC PROCESSING

(75) Inventor: Jeffrey E. Krampert, Topsfield, MA (US)

(73) Assignee: VARIAN SEMICONDUCTOR EQUIPMENT ASSOCIATES, INC., Gloucester, MA (US)

(21) Appl. No.: 13/071,049

(22) Filed: Mar. 24, 2011

(51) Int. Cl. H01J 37/08; F16J 15/02

(52) U.S. Cl. 250/492.21; 277/628

(57) ABSTRACT

In an ion implanter, an elastomer seal is used for cryogenic processing and includes an internal cavity defined by a pair of opposing side walls and a bottom wall disposed therebetween. An electrically conductive spring is disposed within the cavity and extends along a length of the seal. The seal is configured to provide a lateral biasing force against the pair of opposing side walls and to conduct an applied current which results in heat being generated that emanates at least along the pair of opposing side walls. In this manner, the heat from the spring maintains the temperature of the seal above its brittle point. This allows the elastomer seal to maintain its pliability and consequently its sealing integrity during processing at cryogenic temperatures.

### BACKGROUND OF THE INVENTION

1. Field of the Invention

Embodiments of the invention relate to the field of semiconductor device fabrication. More particularly, the present invention relates to a reliable seal used in cryogenic processing environments.

2. Discussion of Related Art

Ion implantation is a process used to dope impurity ions into a semiconductor substrate to obtain desired device characteristics. An ion beam is directed from an ion source chamber toward a substrate. The depth of implantation into the substrate is based on the ion implant energy and the mass of the ions generated in the source chamber. One or more ion species may be implanted at different energy and dose levels to obtain desired device structures. In addition, the beam dose (the amount of ions implanted in the substrate) and the beam current (the uniformity of the ion beam) can be manipulated to provide a desired doping profile in the substrate. However, throughput or manufacturing of semiconductor devices is highly dependent on the uniformity of the ion beam on the target substrate to produce the desired semiconductor device characteristics.

It has been discovered that a relatively low target substrate or wafer temperature during ion implantation improves implant performance. In particular, lower wafer temperatures reduce the amount of damage caused when ions hit the substrate (“damage layer”) which improves device leakage currents. This allows manufacturers to create abrupt source-drain extensions and ultra-shallow junctions needed for today's semiconductor devices. When the temperature of the wafer is decreased, the thickness of the amorphous silicon layer increases because of a reduction in the self-annealing effect.

Typically, cooling of the target substrate to cryogenic temperatures is done by cooling the platen upon which the substrate is disposed in the range of below room temperature to about −100° C. Almost all existing low-temperature ion implanters cool wafers directly during ion implantation. In order to maintain sufficient contact between the cooling elements within the wafer processing vacuum and to provide for efficient thermo-coupling, a reliable gas seal must be maintained. In particular, seals are disposed between the cooling elements and the platen to prevent gas leakage and to maintain the vacuum chamber housing and the target wafer at the desired temperature. These seals are typically made from, for example, polyvinyl chloride, elastomers such as thermoplastic elastomers and/or other plastic materials. In order for the seals to provide a uniform seal between the cold sealing surfaces, they must be pliable. However, at cryogenic processing temperatures, PVC, TPE and other elastomer materials become brittle at approximately −20° C. and −60° C., respectively. Since wafer cryogenic processing is typically performed at temperatures down to −100° C., these seals may become brittle during processing. This may compromise thermocoupling between components. This may affect the vacuum environment for processing tools which may negatively impact manufacturing and device throughput. Consequently, there is a need to provide seals disposed between components in semiconductor processing equipment that maintain their sealing properties and pliability at cryogenic processing temperatures.

### SUMMARY OF THE INVENTION

Exemplary embodiments of the present invention are directed to a seal used in cryogenic processing environments. In an exemplary embodiment, the seal includes an internal cavity defined by a pair of opposing side walls and a bottom wall disposed therebetween; and an electrically conductive spring disposed within the cavity and extending along a length of the seal. The spring is configured to provide a lateral biasing force against the pair of opposing side walls and to conduct an applied current from a first end of the spring to a second end of the spring. The current through the spring results in heat within the spring which emanates toward at least the pair of opposing side walls thereby maintaining their pliability and sealing function.

In another exemplary embodiment, an apparatus for use in an ion implanter includes a platen configured to receive a target substrate; a pad disposed beneath the platen where the pad has a plurality of channels configured to receive coolant material therethrough to reduce the temperature of the platen to approximately −100° C. The platen is capable of being displaced along a top surface of the pad. A lip seal is disposed between and in contact with a bottom surface of the platen and the top surface of the pad. The seal has an internal cavity defined by a pair of opposing side walls and a bottom wall disposed therebetween and an electrically conductive spring with is disposed within the cavity and extends along a length of the seal. The spring is configured to provide a lateral biasing force against the pair of opposing side walls and conducts an applied current from a first end of the spring to a second end of the spring. The current results in heat generated from the spring and emanates toward the pair of opposing side walls.

### BRIEF DESCRIPTION OF THE DRAWINGS

FIG. 1 illustrates a block diagram of a representative ion implanter.

FIG. 2 is a side view of an exemplary portion of a vacuum processing assembly of the ion implanter of FIG. 1 in accordance with an embodiment of the present disclosure.

FIG. 3 is a side view of another exemplary portion of a vacuum processing assembly of the ion implanter of FIG. 1 in accordance with an embodiment of the present disclosure.

FIG. 4 is a top view of an exemplary lip seal taken along lines A-A of FIG. 3 in accordance with an embodiment of the present disclosure.

FIG. 5 is a cross sectional view of an exemplary seal taken along lines B-B of FIG. 4 in accordance with an embodiment of the present disclosure.

FIG. 6 is a cross sectional view of an alternative configuration of an exemplary seal taken along lines B-B of FIG. 4 in accordance with an embodiment of the present disclosure.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

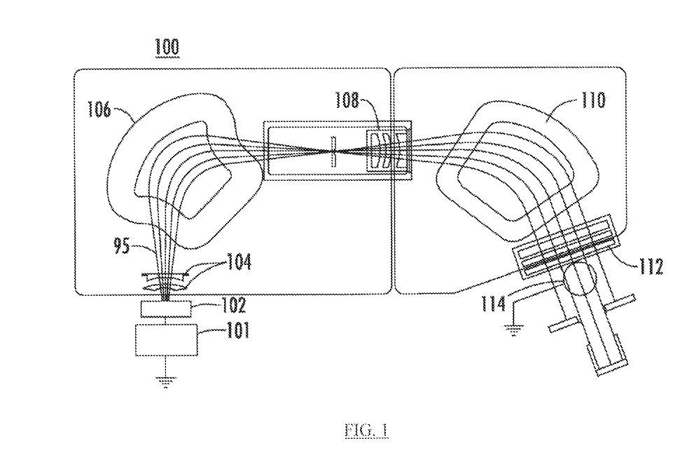

FIG. 1 is a block diagram of an ion implanter 100 including an ion source chamber 102. A power supply 101 supplies the required energy to source 102 which is configured to generate ions of a particular species. The generated ions are extracted from the source through a series of electrodes 104 and formed into a beam 95 which passes through a mass analyzer magnet 106. The mass analyzer is configured with a particular magnetic field such that only the ions with a desired mass-to-charge ratio are able to travel through the analyzer for maximum transmission through the mass resolving slit 107. Ions of the desired species pass from mass slit 107 through deceleration stage 108 to corrector magnet 110. Corrector magnet 110 is energized to deflect ion beamlets in accordance with the strength and direction of the applied magnetic field to provide a ribbon beam targeted toward a work piece or substrate positioned on support (e.g. platen) 114. In some embodiments, a second deceleration stage 112 may be disposed between corrector magnet 110 and support 114. The ions lose energy when they collide with electrons and nuclei in the substrate and come to rest at a desired depth within the substrate based on the acceleration energy.

The ion source chamber 102 typically includes a heated filament which ionizes a feed gas introduced into the chamber to form charged ions and electrons (plasma). The heating element may be, for example, a Bernas source filament, an indirectly heated cathode (IHC) assembly or other thermal electron source. Different feed gases are supplied to the ion source chamber to obtain ion beams having particular dopant characteristics. For example, the introduction of H₂, BF₃ and AsH₃ at relatively high chamber temperatures are broken down into mono-atoms having high implant energies. High implant energies are usually associated with values greater than 20 keV. For low-energy ion implantation, heavier charged molecules such as decaborane, carborane, etc., are introduced into the source chamber at a lower chamber temperature which preserves the molecular structure of the ionized molecules having lower implant energies. Low implant energies typically have values below 20 keV.

FIG. 2 is a side view of an exemplary vacuum processing assembly 200 associated with an ion implanter 100 shown in FIG. 1. Assembly 200 is disposed downstream of the ion beam 95 within a processing chamber maintained at vacuum and is used to provide target wafers or substrates to platen 114 for implantation. Generally, unprocessed target substrates or wafers are typically stored in loadlock chambers (not shown) and transferred to process chamber 200 for processing/implantation and transferred back to one of the loadlocks after processing. The processing assembly 200 includes shaft 201 which supports platen 114 upon which a target substrate or wafer 216 is disposed for processing. A pair of support arms 210a and 210b are disposed below platen 114 and are used to support a pair of thermal pads 208a and 208b. Support arms 210a and 210b may be configured to rotate between an engaged position underneath platen 114 and an open position radially away from the platen 114. Support arms 210a and 210b may be made, for example from aluminum.

The pads 208a and 208b include a plurality of channels 212 to accommodate the flow of coolant, therethrough. The coolant flowing through the channels 212 cools the pads 208a and 208b which in turn cools the platen 114 by contact with a gas heat transfer fluid in the contact area. The wafer 216 is cooled to a desired temperature for ion implantation by platen 114 due to contact therewith and the gas heat transfer fluid in the contact area between the wafer 216 and platen 114. The coolant may be, for example, N2 gas at −180 C. Alternatively, pads 208a and 208b may be integrally formed with respective support arms 210a and 210b and configured with the plurality of channels 212 to accommodate coolant flow. The channels 212 connect to one or more pipes 214 through shaft 201 that provide the coolant and the heat transfer gas to the pads 208a and 208b from a supply source.

Seals 220a, 220b are disposed between pads 208a, 208b (respectively) and platen 114 to form seals there between. Seals 220a, 220b may be formed from an elastomer or other pliable plastic material to form a deformable seal between these components within the vacuum environment. Seals 220a, 220b may be disposed within a channel in either the underside of platen 114 or pads 208a, 208b. The seals 220a, 220b may be referred to as “lip seals” since, as is typical in wafer processing, platen 114 and consequently wafer 216 are displaced in any one of several directions to allow for scanning of beam 95 toward wafer or substrate 216. Seals 220a, 220b may be lip seals which accommodate rotational movement of platen 114 with respect to thermal pads 208a, 208b.

Although seals 220a, 220b are described herein with reference to positioning between platen 114 and pads 208a, 208b, seals 220a and 220b may be disposed between any of the components within a cryogenic processing environment. For example, seals 220a and/or 220b may be used to provide a rotary seal between a shaft, such as shaft 201, and a rotating assembly such as, platen 114. In this configuration, the seal (220a, 220b) is disposed around the shaft 201 between the shaft 201 and the rotating assembly. The shaft 201 typically has passages or channels similar to channels 212 there through to carry cryogenic processing media (e.g. gas) from the stationary shaft 201 to the rotating assembly (e.g. platen 114).

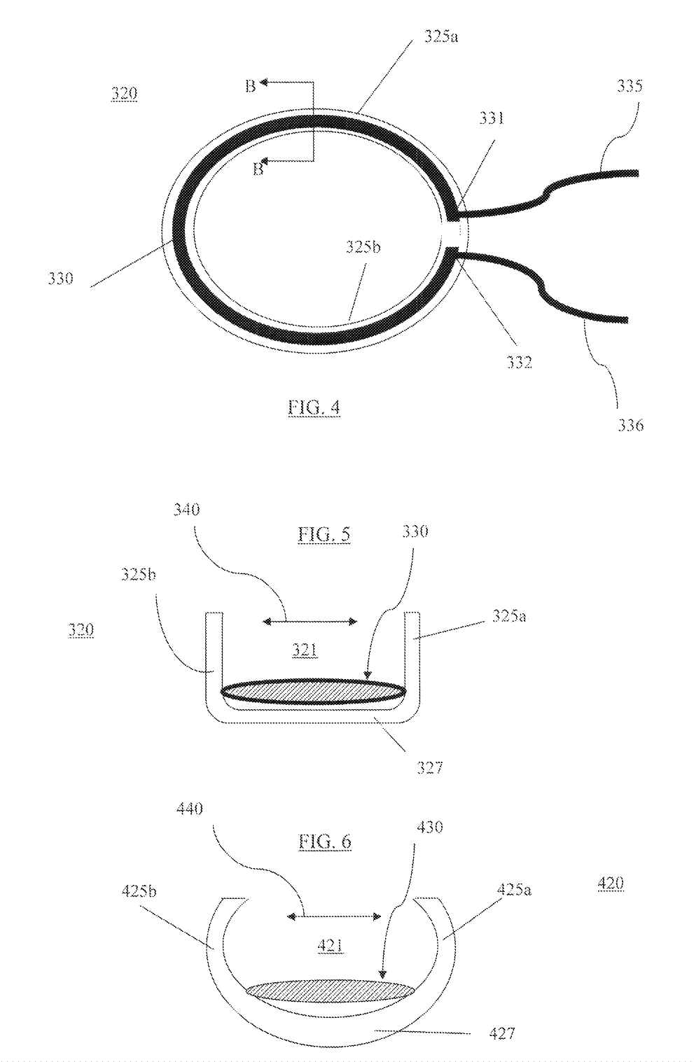

Each of the seals 220a, 220b includes a spring (see FIG. 4) disposed between walls of the seal to provide a lateral or outward biasing force. This lateral force allows the seal to provide relatively tight contact between the platen 114 and respective pads 208a, 208b. Because seals 220a, 220b are in contact with pads 208a, 208b, it is subject to cryogenic processing temperatures in the range from below room temperature to about −100° C. At these low temperatures, the material used to form the seals 220a, 220b would typically become brittle thereby compromising the seal formed between the platen 114 and corresponding pads 208a, 208b. However, a low voltage or current is supplied to the spring within each of the seals 220a, 220b which forms a heater within each seal. The amount of heat supplied from each of the springs to the walls of each seal 220a, 220b prevents the material from becoming brittle thereby maintaining its pliable sealing properties while not being large enough to negatively impact the thermocoupling of cryogenic temperatures from pads 208a, 208b to platen 114.

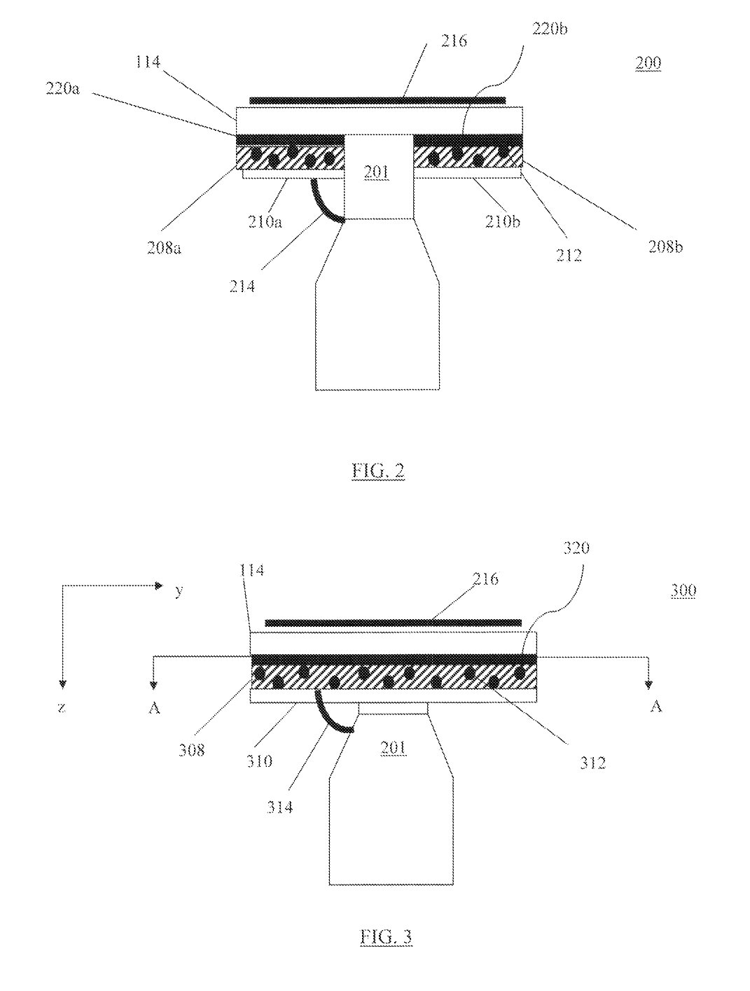

FIG. 3 is a side view of another exemplary vacuum processing assembly 300 associated with an ion implanter 100 shown in FIG. 1. Similar to assembly 200 shown in FIG. 2, assembly 300 is disposed downstream of the ion beam 95 within a processing chamber maintained at vacuum and is used to provide target wafers or substrates to platen 114 for implantation. The processing assembly 300 includes platen 114 used to support a target substrate or wafer 216. In contrast to the assembly 200 shown in FIG. 2 which utilizes a pair of support arms 210a, 210b and a pair of thermal pads 208a, 208b, assembly 300 includes one support arm 310 disposed below platen 114 used to support thermal pad 308 which extends substantially the length of platen 114. Support arm 310 may be configured to move vertically upward to position thermal pad 308 in contact with the underside of platen 114 during wafer processing and to move vertically downward to position thermal pad 308 away from the underside of platen 114 when cryogenic processing is not employed. A thermal pad 308 extends the length of platen 114 and includes a plurality of channels 312 to accommodate the flow of coolant, therethrough. The channels 312 connect to one or more pipes 314 that provide the coolant and the heat transfer gas to the pad 308 from a supply source (not shown). The coolant flowing through the channels 312 cools the pad 308 which in turn cools the platen 114 by contact with a gas heat transfer fluid in the contact area.

In this configuration, a single lip seal 320 is disposed between thermal pad 308 and platen 114. Seal 320 includes a spring 330 (see FIG. 4) disposed between walls of the seal to provide an outward biasing force. A low voltage or current is supplied to the spring within seal 320 which forms a heater within the seal. The amount of heat supplied from the spring 330 to the walls of seal 320 prevents the material from becoming brittle thereby maintaining its pliable sealing properties while not being large enough to negatively impact the thermocoupling of cryogenic temperatures from pad 308 to platen 114.

It should be noted that although seals 220a, 220b, and 320 are being described herein with respect to cryogenic processing in an ion implanter, alternative uses of such a heated lip seal configuration may also be employed where pliability of a seal is required to maintain a gas seal between cryogenic sealing surfaces.

FIG. 4 is a top view of a lip seal 320 taken along lines A-A in FIG. 3. The following description of seal 320 is equally applicable to each of seals 220a, 220b shown in FIG. 2. Seal 320 is shown as having a generally circular shape, however alternative configurations may be employed depending on the geometry of the components disposed on either side of the seal. Seal 320 includes a pair of opposing side walls 325a, 325b and a bottom wall 327 (shown in FIG. 5). These walls may be extruded from an elastomer or other pliable plastic material. Spring 330 is radially disposed toward bottom wall 327 between opposing side walls 325a, 325b. Spring 330 provides a biasing force outward or laterally toward each of side walls 325a and 325b. Spring 330 is made from, for example, a conductive material such as metal and may have a generally circular, helical or other configuration consistent with the requirements of providing an outward biasing force against side walls 325a, 325b and conducting an applied current or voltage.

Spring 330 includes a first end 331 and a second end 332 each connected to a respective electrical wire 335, 336. One of the wires 335, 336 is connected to a power source and the other is connected to neutral to complete a closed loop circuit. When a voltage or current is applied to spring 330 via wires 335, 336, heat is generated through the spring which radiates along the walls 325a, 325b and 327 of seal 320 thereby heating the seal and preventing the seal material from becoming brittle. This heat allows seal 320 to remain pliable during low temperature cryogenic processing. The amount of current applied to spring 330 may be regulated based on the amount needed to generate sufficient heat to keep seal 320 pliable at particular cryogenic processing temperatures. This provides the necessary gas seal required by maintaining the temperature of the seal 320 to be compliant with cryogenic sealing surfaces within the vacuum processing chamber. FIG. 5 is a cross sectional view of lip seal 320 (as well as seals 220a, 220b in FIG. 2) taken along lines B-B of FIG. 4. Seal 320 is defined by opposing side walls 325a, 325b and a bottom wall 327 all of which forms an inner cavity 321. Spring 330 may be disposed toward bottom wall 327 between opposing side walls 325a, 325b and provides a biasing force outward in the direction of arrows 340 toward each of the side walls. This biasing force allows seal 320 to contact cryogenic component surfaces. Side walls 325a, 325b may be angled inward toward each other or a center point of cavity 321 to provide an appropriate surface area to contact the cold sealing surfaces of either platen 114 or pad 308. Spring 330 may be a coil spring that defines a continuous electrical path from the first end 331 to the second end 332. Thus, spring 330 provides a bias force against the side walls 325a, 325b as well as providing a heating element to heat seal 320 to maintain its pliability and consequently its sealing properties.

FIG. 6 is a cross sectional view of an alternative configuration of lip seal 420 (as well as seals 220a, 220b in FIG. 2) taken along lines B-B of FIG. 4. Seal 420 is defined by opposing side walls 425a, 425b and a bottom wall 427 which forms an inner cavity 421. As can be seen, the walls of seal 420 have a radius of curvature as compared to the walls of seal 320. This alternative configuration may be adapted for various uses depending on the shape of the cryogenic sealing surfaces. Spring 430 is disposed within cavity 421 between opposing side walls 425a, 425b and provides a biasing force outward in the direction of arrows 440 toward each of the side walls. This biasing force allows lip seal 420 to contact cryogenic component surfaces. Spring 430 also provides a continuous electrical path to accommodate an applied voltage and current flow to heat spring 430 and consequently maintain the pliability and sealing properties of lip seal 420.

While the present invention has been disclosed with reference to certain embodiments, numerous modifications, alterations and changes to the described embodiments are possible without departing from the sphere and scope of the present invention, as defined in the appended claims. Accordingly, it is intended that the present invention not be limited to the described embodiments, but that it has the full scope defined by the language of the following claims, and equivalents thereof.

What is claimed is:

1. A seal used in cryogenic processing comprising:
an internal cavity defined by a pair of opposing side walls and a bottom wall disposed therebetween; and
an electrically conductive spring disposed within said cavity extending along a length of said seal, said spring configured to provide a lateral biasing force against said pair of opposing side walls and to conduct an applied current from a first end of said spring to a second end of said spring, said current resulting in heat generated from said spring and emanating at least along said pair of opposing side walls.

2. The seal of claim 1 wherein said pair of opposing side walls each have a radius of curvature about a center point within said cavity.

3. The seal of claim 1 wherein said seal has a generally circular shape, said spring extending substantially around said seal within said cavity.

4. The seal of claim 1 further comprising a first wire connected to said first end of said spring and a second wire connected to said second end of said spring, said first and second wires defining a means to connect said spring to a power supply.

5. The seal of claim 1 wherein said spring is a coil spring having a cross sectional area less than a distance between said opposing side walls.

6. The seal of claim 1 wherein a first of said pair of opposing side walls is in contact with a first cryogenic surface and a second of said pair of opposing side walls is in contact with a second cryogenic surface, each of said first and second cryogenic surfaces within the range of approximately −100° C.

7. The seal of claim 1 wherein said heat emanates along said bottom wall of said seal.

8. The seal of claim 1 wherein each of said pair of opposing side walls and said bottom wall are made from an elastomer material.

9. An apparatus for use in an ion implanter comprising:
a platen configured to receive a target substrate;
a pad disposed beneath said platen, said pad having a plurality of channels configured to receive coolant material therethrough to thermocouple said coolant to said platen to reduce the temperature of said platen to approximately −100° C., said platen capable of being displaced along a top surface of said pad;
a lip seal disposed between and in contact with a bottom surface of said platen and said top surface of said pad, said seal having an internal cavity defined by a pair of opposing side walls and a bottom wall disposed therebetween and an electrically conductive spring disposed within said cavity extending along a length of said seal, said spring configured to provide a lateral biasing force against said pair of opposing side walls and to conduct an applied current from a first end of said spring to a second end of said spring, said current resulting in heat generated from said spring and emanating toward said pair of opposing side walls.

10. The apparatus of claim 9 further comprising a first wire connected to said first end of said spring and a second wire connected to said second end of said spring, said first and second wires defining a means to connect said spring to a power supply.

11. The apparatus of claim 9 wherein said spring is a coil spring having a cross sectional area less than a distance between said opposing side walls.

12. The apparatus of claim 9 wherein each of said pair of opposing side walls and said bottom wall are made from an elastomer material.
